(19) United States
(12) Patent Application Publication
(10) Pub. No.: US 2024/0206255 A1
(43) Pub. Date: Jun. 20, 2024

(54) DISPLAY DEVICE

(71) Applicant: LG Display Co., Ltd., Seoul (KR)

(72) Inventor: Geunuk KIM, Hadong-gun (KR)

(73) Assignee: LG Display Co., Ltd., Seoul (KR)

(21) Appl. No.: 18/388,119

(22) Filed: Nov. 8, 2023

(30) Foreign Application Priority Data
Dec. 19, 2022 (KR) 10-2022-0178550

(51) Int. Cl. H10K 59/131

(52) U.S. Cl. CPC H10K 59/131; H10K 2102/311

(57) ABSTRACT

A display device including a display panel including a display area and a non-display area is discussed. The non-display area has a first area and a second area, a plurality of first lines and a plurality of second lines disposed in the display area and extending in a first direction, a plurality of third lines and a plurality of fourth lines disposed in the second area, a plurality of fifth lines connecting the plurality of first lines and the plurality of third lines to each other, respectively, and a plurality of sixth lines and a plurality of seventh lines connecting the plurality of second lines and the plurality of fourth lines to each other, respectively. The plurality of sixth lines and the plurality of seventh lines are respectively connected to each other. Each of the plurality of sixth lines extends in a second direction different from the first direction.

### CROSS-REFERENCE TO RELATED APPLICATION

This application claims priority to Korean Patent Application No. 10-2022-0178550 filed on Dec. 19, 2022, the entire contents of which are hereby expressly incorporated by reference into the present application.

### BACKGROUND

### Field

The present disclosure relates to a display device.

### Discussion of Related Art

Since the beginning of the information age, users' demand for functionality of display devices that display images is increasing. Thus, various types of display devices such as liquid crystal display devices, organic light-emitting display devices, etc. are being developed and put into use.

The display device used in computer monitors, TVs, mobile phones, etc. includes an organic light-emitting display device (OLED) that emits light by itself, and a liquid crystal display device (LCD) that requires a separate light source, among others.

Compared to the liquid crystal display device, the organic light-emitting display device does not use a separate light source but uses a self-emitting light-emitting element that can generate its own light, and thus is becoming the mainstream technology in the display field due to a small thickness and excellent image quality that can be provided. In particular, in the organic light-emitting display device, the light-emitting element can be formed on a flexible substrate, such that a screen can be configured in various forms so as to be bent or folded. Thus, the organic light-emitting display device can be applied to various display devices that are foldable.

The organic light-emitting display device can include a display panel and various components to provide various functions. A plurality of driver circuits for providing various types of additional functions, for example, touch sensing or fingerprint identification functions, can be included in the display device. Some components with specific functions can be disposed in a display area of the display panel, and other components with other functions can be disposed on a non-display area adjacent to the display area.

The display panel can include a plurality of signal lines connecting a plurality of sub-pixels of the display area and the driver circuits to each other. In turn, the signal lines can be connected to the driver circuit via a pad disposed in the non-display area of the display panel.

As display devices diversify, a user can come to prefer a mobile product with a large screen/device ratio. Accordingly, research and development are being attempted and ongoing to increase the screen/device ratio, for example, to implement a narrow bezel in which a ratio of a size of the non-display area to a size of the display area is reduced.

### SUMMARY OF THE DISCLOSURE

A purpose of embodiments of the present disclosure is to provide a display device in which a space occupied by the signal line disposed in the non-display area of the display panel and connected to the driver circuit is reduced, thereby reducing a size of the non-display area.

Purposes according to the present disclosure are not limited to the above-mentioned purpose. Other purposes and advantages according to the present disclosure that are not mentioned can be understood based on following descriptions, and can be more clearly understood based on embodiments according to the present disclosure. Further, it will be easily understood that the purposes and advantages according to the present disclosure can be realized using means shown in the claims or combinations thereof.

A display device according to an embodiment of the present disclosure includes a display panel including a display area and a non-display area, wherein the non-display area has a first area and a second area; a plurality of first lines and a plurality of second lines disposed in the display area and extending in a first direction; a plurality of third lines and a plurality of fourth lines disposed in the second area; a plurality of fifth lines connecting the plurality of first lines and the plurality of third lines to each other, respectively; and a plurality of sixth lines and a plurality of seventh lines connecting the plurality of second lines and the plurality of fourth lines to each other, respectively, wherein the plurality of sixth lines and the plurality of seventh lines are respectively connected to each other, wherein each of the plurality of sixth lines extends in a second direction different from the first direction, wherein each of the plurality of seventh lines extends in the first direction.

A display device according to an embodiment of the present disclosure includes a display panel including a display area and a non-display area, wherein the non-display area has a first area and a second area; and a first continuously-connected line and a second continuously-connected line disposed in the display panel, wherein the first continuously-connected line and the second continuously-connected line intersect each other in each of the display area and the second area.

According to the embodiment of the present disclosure, the size of the non-display area can be reduced by reducing the space occupied by the connection line disposed in the non-display area of the display panel and connected to the driver circuit. As a result, the bezel area can be minimized, such that the appearance characteristics of the display device can be improved.

According to the embodiment of the present disclosure, process optimization can be achieved to reduce the size of the non-display area. Thus, a manufacturing cost of the display device can be reduced.

In addition to the effects as described above, specific effects of the present disclosure will be described together while describing specific details for carrying out the present disclosure.

### BRIEF DESCRIPTION OF DRAWINGS

The present disclosure will become more fully understood from the detailed description given hereinbelow and the accompanying drawings which are given by way of illustration only, and thus are not limitative of the present disclosure.

FIG. 1 is a diagram showing a configuration of a display device according to an embodiment of the present disclosure.

FIG. 2 is a circuit diagram of a sub-pixel according to an embodiment of the present disclosure.

FIG. 3 is an enlarged view of an area A in FIG. 1.

FIG. 4 is an enlarged view of an area B of FIG. 3 according to an embodiment of the present disclosure.

FIG. 5 is an enlarged view of an area B of FIG. 3 according to another embodiment of the present disclosure.

FIG. 6 is a diagram illustrating an area B of FIG. 3 and an area around the area B according to an embodiment of the present disclosure.

FIG. 7 is a three-dimensional view of a line according to an embodiment of the present disclosure.

FIG. 8A to FIG. 8C are cross-sectional views cut along cut lines C-C′, D-D′, and E-E′, respectively, in FIG. 7.

FIG. 9 is a cross-sectional view of a line disposed in a second area according to an embodiment of the present disclosure.

### DETAILED DESCRIPTION OF THE EMBODIMENTS

Advantages and features of the present disclosure, and a method of achieving the advantages and features will become apparent with reference to embodiments described later in detail together with the accompanying drawings. However, the present disclosure is not limited to the embodiments as disclosed under, but can be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included within the spirit and scope of the present disclosure as defined by the appended claims.

A shape, a size, a ratio, an angle, a number, etc. disclosed in the drawings for describing embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements can modify the entire list of elements and need not modify the individual elements of the list. In interpretation of numerical values, an error or tolerance therein can occur even when there is no explicit description thereof.

In addition, it will also be understood that when a first element or layer is referred to as being present “on” a second element or layer, the first element can be disposed directly on the second element or can be disposed indirectly on the second element with a third element or layer being disposed between the first and second elements or layers. It will be understood that when an element or layer is referred to as being “connected to”, or “coupled to” another element or layer, it can be directly on, connected to, or coupled to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

Further, as used herein, when a layer, film, region, plate, or the like is disposed “on” or “on a top” of another layer, film, region, plate, or the like, the former can directly contact the latter or still another layer, film, region, plate, or the like can be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former can directly contact the latter or still another layer, film, region, plate, or the like can be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is not indicated.

When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms “first”, “second”, “third”, and so on can be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range unless there is no separate explicit description thereof.

It will be understood that when an element or layer is referred to as being “connected to”, or “coupled to” another element or layer, it can be directly on, connected to, or coupled to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

The features of the various embodiments of the present disclosure can be partially or entirely combined with each other, and can be technically associated with each other or operate with each other. The embodiments can be implemented independently of each other and can be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “display device” can include, in a narrow sense, a display device including a liquid crystal module (LCM), an organic light-emitting diode (OLED) module, or a quantum dot (QD) module including a display panel and a driver for driving the display panel. Moreover, the display device can include, in a broad sense, a laptop computer, a television, a computer monitor, an automotive device or an equipment display for a vehicle, a set electronic device, a set device or a set apparatus including a complete product or a final product including the LCM, the OLED module, or the QD module.

Therefore, the display device in accordance with the present disclosure can include, in the narrow sense, a display device itself including, for example, the LCM, the OLED module, QD module, etc., and can include, in a broad sense, the set device as an application product or an end-user device including a complete product or a final product including the LCM, the OLED module, or the QD module.

Moreover, in some cases, the LCM, OLED module, or QD module composed of the display panel and the driver can be expressed as “display device” in a narrow sense. The electronic device as a complete product including the LCM, OLED module or QD module can be expressed as “set device” in a broad sense. For example, the display device in the narrow sense can include a display panel such as a liquid crystal panel, an organic light-emitting display panel, or a quantum dot display panel, and a source PCB as a controller for driving the display panel. The set device in the broad sense can include a display panel such as a liquid crystal panel, an organic light-emitting display panel, or a quantum dot display panel, a source PCB as a controller for driving the display panel, and a set PCB as a set controller that is electrically connected to the source PCB and controls the set device.

As used herein, the display panel can be of any type of the display panels such as a liquid crystal display panel, an organic light emitting diode (OLED) display panel, a quantum dot (QD) display panel, and an electroluminescent display panel, etc. The display panel used in the present disclosure may be not limited to a specific display panel including a flexible substrate for the OLED display panel and an underlying back plate support structure and having a bendable bezel. Moreover, the display panel used in the display device according to an embodiment of the present disclosure is not limited to a shape or a size of the display panel.

For example, when the display panel is embodied as the organic light emitting diode (OLED) display panel, the display panel can include a plurality of gate lines and data lines, and pixels respectively formed in areas where the gate lines and the data lines intersect with each other. Moreover, the display panel can be configured to include an array including a thin-film transistor as an element for selectively applying a voltage to each pixel, an organic light-emitting element layer on the array, and an encapsulation substrate or an encapsulation layer disposed on the array to cover the organic light-emitting element layer. The encapsulation layer protects the thin-film transistor and the organic light-emitting element layer from external impact, and can prevent moisture or oxygen from penetrating into the organic light-emitting element layer. Moreover, the light emitting layer formed on the array can include an inorganic light emitting layer, for example, a nano-sized material layer, or a quantum dot.

Hereinafter, an embodiment of a display device in which a space occupied by a connection line disposed in a non-display area of a display panel and connected to a driver circuit can be reduced, thereby reducing a size of a non-display area will be described in detail. All components of each display device according to all embodiments of the present disclosure are operatively coupled and configured.

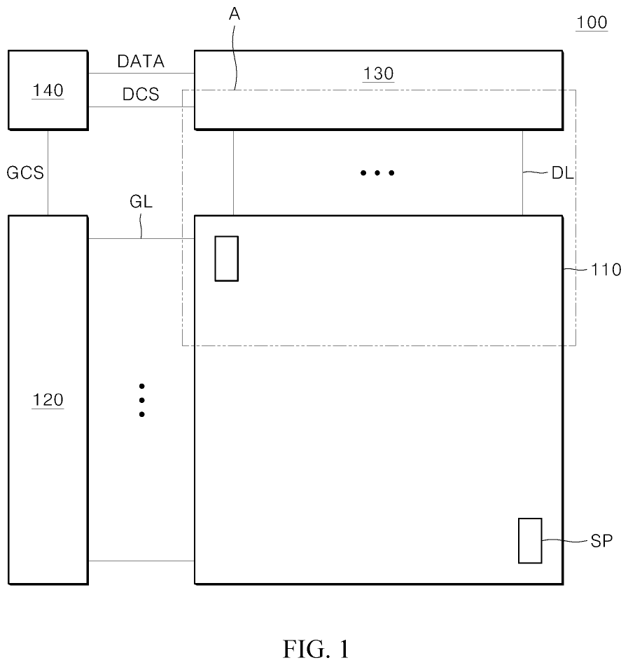

FIG. 1 is a diagram showing a configuration of a display device according to an embodiment of the present disclosure.

Referring to FIG. 1, a display device 100 according to an embodiment of the present disclosure can include a display panel 110 in which a plurality of gate lines GL, a plurality of data lines DL, and a plurality of sub-pixels SP are disposed, a gate driver circuit 120 connected to the plurality of gate lines GL, a data driver circuit 130 connected to the plurality of data lines DL, and a controller 140 controlling the gate driver circuit 120 and the data driver circuit 130.

The display panel 110 can include a display area or an active area (AA) in which a plurality of sub-pixels SP displaying an image are disposed, and a non-display area or a non-active area NA located out of the display area AA. For example, the non-display area NA can be disposed around the display area AA.

The gate driver circuit 120 can output a scan signal to the plurality of gate lines GL to control an operation timing of the sub-pixel SP disposed in the display panel 110.

The gate driver circuit 120 can sequentially supply the scan signal of an on-voltage or an off-voltage to the plurality of gate lines GL to sequentially drive the plurality of gate lines GL under control of the controller 140.

The gate driver circuit 120 can be located on only one side of the display panel 110 or on each of both opposing sides according to a driving scheme. The gate driver circuit 120 can include one or more gate driver integrated circuits (GD-IC). However, embodiments of the present disclosure are not limited thereto.

Each gate driver integrated circuit GD-IC can be disposed in each of various positions. For example, each gate driver integrated circuit GD-IC can be disposed on at least one side of the display panel 110 and can be connected to a bonding pad (a panel pad) of the display panel 110 in a tape automated bonding (TAB) scheme. For example, each gate driver integrated circuit GD-IC can be implemented as a GIP (gate in panel) type circuit in a chip on glass (COG) scheme and can be directly disposed in the display panel 110. However, the present disclosure is not limited thereto.

For example, each gate driver integrated circuit GD-IC can be implemented in a chip on film (COF) scheme in which the gate driver circuit 120 is mounted on a film connected to the display panel 110. However, the present disclosure is not limited thereto.

The data driver circuit 130 can output a data voltage to each sub-pixel SP through the data line DL at a timing when the scan signal is applied through the gate line GL so that each sub-pixel SP can display an image of brightness according to image data.

When a specific gate line GL is opened, the data driver circuit 130 converts the image data received from the controller 140 into an analog data voltage and supplies the converted data voltage to the plurality of data lines DL to drive the plurality of data lines DL.

The data driver circuit 130 can include at least one source driver integrated circuit (SD-IC) to drive the plurality of data lines DL.

Each source driver integrated circuit SD-IC can be disposed in each of various positions. For example, each source driver integrated circuit SD-IC can be disposed on one side of the display panel 110 and can be connected to the bonding pad (the panel pad) of the display panel 110 in a tape automated bonding (TAB) scheme. For example, each source driver integrated circuit SD-IC can be integrated into the display panel 110. However, the present disclosure is not limited thereto.

For example, each source driver integrated circuit SD-IC can be implemented in a chip on film (COF) scheme in which the data driver circuit 130 is mounted on a film to which the display panel 110 is connected. In this case, one side of the source driver integrated circuit SD-IC can be bonded to at least one source printed circuit board S-PCB, and the other side thereof can be bonded to the display panel 110.

The controller 140 can supply various control signals to the gate driver circuit 120 and the data driver circuit 130, and can control operations of the gate driver circuit 120 and the data driver circuit 130.

The controller 140 can start scanning according to a timing implemented in each frame, and can convert input image data (or external data) received from an external source so as to comply with a data signal format used by the data driver circuit 130, and can output the converted image data DATA to the data driver circuit 130, and can control data driving of the data driver circuit 130 at an appropriate time according to the scanning.

The controller 140 can receive various timing signals including a vertical synchronization signal Vsync, a horizontal synchronization signal Hsync, an input data enables signal DE: Data Enable, and a clock signal CLK along with the input image data from an external device, for example, a host system.

The controller 140 can convert the input image data received from the external device so as to comply with the data signal format used by the data driver circuit 130 and can output the converted image data DATA to the data driver circuit 130. Further, in order to control the gate driver circuit 120 and the data driver circuit 130, the controller 140 can generate various control signals using the input timing signals and output the generated various control signals to the gate driver circuit 120 and the data driver circuit 130.

For example, in order to control the gate driver circuit 120, the controller 140 can output various gate control signals including a gate start pulse GSP, a gate shift clock GSC, a gate output enable signal GOE, etc. to the gate driver circuit 120.

For example, the gate start pulse GSP can control an operation start timing of one or more gate driver integrated circuits GD-IC constituting the gate driver circuit 120. For example, the gate shift clock GSC can be a clock signal commonly input to one or more gate driver integrated circuits GD-IC, and can control a shift timing of the scan signal. For example, the gate output enable signal GOE can designate timing information of one or more gate driver integrated circuits GD-IC.

In order to control the data driver circuit 130, the controller 140 can output various data control signals DCS including a source start pulse SSP, a source sampling clock SSC, a source output enable signal SOE, etc. to the data driver circuit 130.

For example, the source start pulse SSP can control a data sampling start timing of one or more source driver integrated circuit SD-IC constituting the data driver circuit 130. For example, the source sampling clock SSC can be a clock signal that controls a sampling timing of the data in each source driver integrated circuit SD-IC. For example, the source output enable signal SOE can control an output timing of the data driver circuit 130.

The controller 140 can be disposed in a control printed circuit board C-PCB. The control printed circuit board C-PCB can be connected to the source printed circuit board S-PCB via a connection medium such as a flexible flat cable (FFC), or a flexible printed circuit (FPC). However, the present disclosure is not limited thereto.

A power controller can be disposed in the control printed circuit board C-PCB. The power controller can supply various voltages or currents to the display panel 110, the gate driver circuit 120, and the data driver circuit 130, or can control various powers or currents to be supplied thereto.

A signal line disposed in the display panel 110 can be connected to a pad or a panel pad of the display panel 110, and can be connected to the driver circuit via the pad or the panel pad.

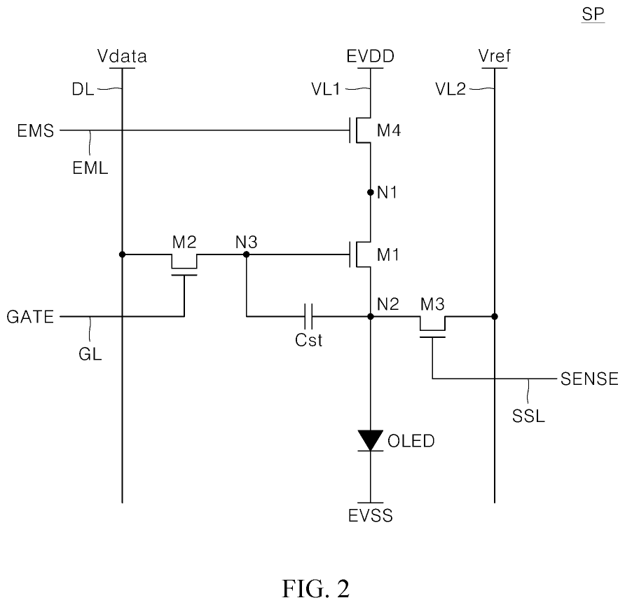

FIG. 2 is a circuit diagram of a configuration of a sub-pixel according to an embodiment of the present disclosure.

Referring to FIG. 2, the sub-pixel SP can include a first transistor M1, a second transistor M2, a third transistor M3, a storage capacitor Cst, and a light-emitting diode LED. In FIG. 2, a structure of the sub-pixel SP has a 4T1C structure composed of 4 transistors and 1 storage capacitor Cst by way of example. However, the present disclosure is not limited thereto. For example, the structure of the sub-pixel SP can be a structure such as 6T1C, 6T2C, 7T1C, and the like.

A first electrode of the first transistor M1 can be connected to a first node N1 connected to a first power line VL1 to which a first power EVDD is delivered. A second electrode of the first transistor M1 can be connected to a second node N2. A gate electrode of the first transistor M1 can be connected to a third node N3. The first transistor M1 can allow a driving current resulting from the first power EVDD supplied to the first node N1 to flow to the second electrode thereof in response to a voltage delivered to the gate electrode of the first transistor M1.

A first electrode of the second transistor M2 can be connected to the data line DL delivering the data voltage Vdata, and a second electrode of the second transistor M2 can be connected to the third node N3. A gate electrode of the second transistor M2 can be connected to the gate line GL that supplies a gate signal GATE. The second transistor M2 can receive the gate signal and supply the data voltage Vdata transmitted to the data line DL to the gate electrode of the first transistor M1. The gate signal can be supplied from the gate driver circuit 120 as shown in FIG. 1.

A first electrode of the third transistor M3 can be connected to a second power line VL2 delivering a reference voltage Vref, and a second electrode of the third transistor M3 can be connected to the second node N2. A gate electrode of the third transistor M3 can be connected to a sensing line SSL. The third transistor M3 can receive a sensing signal SENSE and apply the reference voltage Vref transmitted to the second power line VL2 to the second electrode of the first transistor M1. The second node N2 can be initialized by the reference voltage Vref. The sensing signal SENSE can be supplied from the gate driver circuit 120 as shown in FIG. 1. The data signal can be supplied from the data driver circuit 130 as shown in FIG. 1.

A first electrode of the storage capacitor Cst can be connected to the third node N3, and a second electrode of the storage capacitor Cst can be connected to the second node N2. The storage capacitor Cst can be disposed between and connected to the gate electrode of the first transistor M1 and the second electrode of the first transistor M1 so as to maintain a difference between a voltage of the gate electrode of the first transistor M1 and a voltage of the second electrode of the first transistor M1.

An anode electrode of the light-emitting diode OLED can be connected to the second node N2, and a cathode electrode thereof can be connected to a second power EVSS. A voltage level of the second power EVSS can be lower than a voltage level of the first power EVDD. The light-emitting diode OLED can emit light in response to the current flowing from the anode electrode to the cathode electrode. The light-emitting diode OLED can include a light-emissive layer that emits light based on the current flowing between the anode electrode and the cathode electrode. The light-emissive layer can be embodied as an organic material layer. However, embodiments of the present disclosure are not limited thereto.

In the sub-pixel SP configured as described above, each of the first transistor M1 and the second transistor M2 can be embodied as an N MOS type transistor, and the third transistor M3 can be embodied as a P MOS type transistor. However, the present disclosure is not limited thereto. The first electrode and the second electrode of each of the first to third transistors M1 to M3 can be a drain electrode and a source electrode, respectively. However, the present disclosure is not limited thereto.

The driving current supplied from the first transistor M1 can be expressed based on a following Equation 1:

$$Id = {k ( V g s - V t h )}^{2} \qquad [ Equation 1 ]$$

In this regard, Id represents an amount of the driving current supplied from the first transistor M1, Vgs represents the difference between the voltage of the gate electrode of the first transistor M1 and the voltage of the source electrode thereof, and Vth represents a threshold voltage of the first transistor M1. Further, k represents mobility.

Based on the above Equation 1, the driving current corresponds to the difference between the voltages of the gate electrode and the source electrode of the first transistor M1. Thus, when the second electrode is the source electrode, and when the data voltage Vdata corresponding to the data signal is transmitted to the source electrode, and the reference voltage Vref is transmitted to the gate electrode, the driving current can flow in response to the data signal.

The sub-pixel SP can include a fourth transistor M4. A first electrode of the fourth transistor M4 can be connected to the first power line VL1 supplying the first power EVDD, and a second electrode thereof can be connected to the first node N1. Further, a gate electrode of the fourth transistor M4 can be connected to a light-emission control signal line EML that transmits a light-emission control signal EMS. The light-emission control signal line EML can be connected to the gate driver circuit 120 as shown in FIG. 1 and can receive the light-emission control signal from the gate driver circuit 120.

When the fourth transistor M4 is turned on based on the light-emission control signal, a voltage of the first power EVDD can be applied to the first node N1. The fourth transistor M4 can be embodied as an N MOS type transistor. However, the present disclosure is not limited thereto.

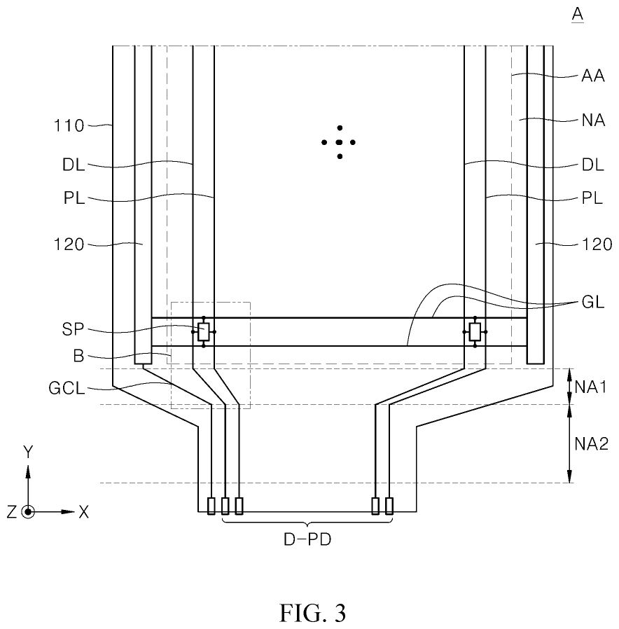

FIG. 3 is an enlarged view of an area A in FIG. 1.

Referring to FIG. 3, in the display device according to an embodiment of the present disclosure, the display panel 110 can include the display area AA and the non-display area NA. In the display area AA, a plurality of lines connected to the plurality of sub-pixels SP disposed in the display area AA can be disposed. An internal driver circuit, a plurality of connection lines, and a plurality of display panel pads D-PD can be disposed in the non-display area NA. The non-display area NA can include a first area NA1 and a second area NA2. For example, the display panel pad D-PD can be a first pad. However, embodiments of the present disclosure are not limited thereto.

The plurality of sub-pixels SP and the plurality of lines connected to the plurality of sub-pixels SP so as to provide the driving power and signals thereto can be disposed in the display area AA. For example, the plurality of lines can include the gate line GL, the data line DL, and the power line PL. However, the present disclosure is not limited thereto.

The driver circuit connected to the sub-pixel SP of the display area AA, the connection lines, and the plurality of display panel pads D-PD can be disposed in the non-display area NA.

The driver circuit can be disposed in and/or out of the display panel 110. The driver circuit according to an embodiment of the present disclosure can be disposed in the non-display area NA of the display panel 110 in a GIP (gate in panel) scheme. For example, the internal driver circuit can be the gate driver circuit 120. However, the present disclosure is not limited thereto.

The gate driver circuit 120 can be disposed on one side of the display area AA. However, the present disclosure is not limited thereto. For example, the gate driver circuit 120 can be disposed at each of several locations in the non-display area NA.

The plurality of display panel pads D-PD can be disposed on one side of the non-display area NA. One end of each of the plurality of display panel pads D-PD can be connected to each of the plurality of lines of the display area AA, for example, the gate line GL, the data line DL, and the power line PL via each of the connection lines. The other end of each of the plurality of display panel pads D-PD can be electrically connected to each driving pad of the driver circuit outside the display panel 110, for example, to each driving pad of the data driver circuit 130 of FIG. 1.

When the gate driver circuit 120 is configured in the GIP scheme, some of the plurality of display panel pads D-PD can be connected to a plurality of gate control lines GCL connected to the gate driver circuit 120. For example, the gate control line GCL can be connected to the display panel pad D-PD and can transfer a driving control signal from the external controller (140 of FIG. 1) to the gate driver circuit 120. However, the present disclosure is not limited thereto.

The non-display area NA can include the first area NA1 and the second area NA2.

In the second area NA2, the plurality of connection lines (or link lines) connecting the various signal lines of the display area AA and the non-display area NA and the display panel pads D-PD to each other can be disposed. One side of the second area NA2 can come into contact with the first area NA1 where the connection line (or the link line) is disposed. The other side of the second area NA2 can come into contact with an area in which the display panel pads D-PD are disposed. For example, the other side can be different from and can be opposite to one side. The second area NA2 can be a bent area. The second area NA2 of the display panel 110 in which the plurality of connection lines extending toward the display panel pads D-PD are disposed can be bent toward a rear surface of the display panel 110. For example, the second area NA2 can be bent toward the rear surface of the display panel 110 at a predetermined curvature based on a second direction (or an X-axis direction). Accordingly, a size of a portion of the non-display area AA constituting a front surface of the display device 100 can be reduced to minimize the bezel area, such that the outer appearance of the display device 100 can be improved.

The other side of the second area NA2 bent to the rear surface of the display panel 110 or a structure connected to the other side can be fixed to the rear surface of the display panel 110. For example, the other side of the second area NA2 or the structure connected to the other side can be fixed to the rear surface of the display panel 110 via an adhesive member. For example, a fixing force can be applied to the other side of the second area NA2 or to the structure connected to the other side.

When the display panel 110 is bent at the second area NA2, the display panel 110 can be affected by a restoring force. The display panel 110 can be composed of a flexible substrate, and can be bent at a very small curvature in order to reduce the size of the portion of the non-display area NA constituting the front surface of the display device 100. In order to maintain the bent state of the display panel 110 at the second area NA2, the fixing force can be greater than the restoring force.

The fixing force and/or the restoring force of the display panel 110 in the second area NA2 can depend on a width of the display panel 110. For example, as the width of the display panel 110 increases, the restoring force can increase, and thus a stronger fixing force can be required.

In order to reduce the restoring force of the display panel 110 as bent in the second area NA2, the width of the display panel 110 in the second area NA2 can be reduced. The minimum width of the second area NA2 of the display panel 110 can depend on the width of an area in which the plurality of display panel pads D-PD disposed at the other side of the second area NA2 are disposed. For example, the minimum width of the second area NA2 can be a sum of widths of the plurality of display panel pads D-PD and spacings between adjacent ones of the plurality of display panel pads D-PD. For example, the width of the display panel 110 in the second area NA2 can be smaller than a width of the display panel 110 in the display area AA.

The plurality of connection lines (or link lines) connecting the various signal lines of the display area AA and the non-display area NA to the display panel pads D-PD can be disposed in the first area NA1. One side of the first area NA1 can come into contact with the display area AA. The other side of the first area NA1 can contact the second area NA2. For example, the other side can be different from and can be opposite to one side. A width of the display panel 110 in the first area NA1 need not be constant. For example, the first area NA1 can be an area where a width of the display panel 110 in the display area AA transitions to a width of the display panel 110 in the second area NA2. For example, a shape of the display panel 110 in the first area NA1 can be an inverted trapezoid. However, the present disclosure is not limited thereto.

The first area NA1 of the display panel 110 have an area in which a spacing between adjacent ones of some of the plurality of connection lines decreases as the area extends toward the second area NA2. For example, a spacing between two adjacent connection lines of the first area NA1 respectively connected to two adjacent lines located in an outermost portion of the display area AA can decrease as the two adjacent connection lines extend toward the second area NA2. For example, the plurality of connection lines can be arranged in a radial manner in the first area NA1. However, the present disclosure is not limited thereto.

An area size (or a width) of the first area NA1 can depend on the number and a configuration of the sub-pixels SP and the number of components included in the display panel 110 for additional functions such as touch sensing and fingerprint identification. For example, when a resolution of the display area AA increases and thus the number of sub-pixels SP increases, the number of the connection lines disposed in the first area NA1 can increase and thus the area size of the first area NA1 can increase. For example, when the number of transistors or passive elements included according to the configuration of the sub-pixel SP increases, the number of the connection lines disposed in the first area NA1 can increase, and thus the area size of the first area NA1 can increase. For example, when the number of the components included in the display panel 110 increases, the number of the connection lines disposed in the first area NA1 can increase, and thus the area size of the first area NA1 can increase.

The first area NA1 is included in the non-display area NA. Thus, when the area size of the first area NA increases, the bezel area increases, such that it can be difficult to implement the narrow bezel.

Accordingly, the inventors of the present disclosure have recognized the above-mentioned problems and have conducted various studies and experiments to reduce a size of the first area NA1 of the non-display area NA to implement a narrow bezel or bezel-free display device. Through various studies and experiments, the inventors of the present disclosure have invented a novel display device in which the size of the first area NA1 is reduced to reduce the bezel area and to improve the appearance characteristics of the display device.

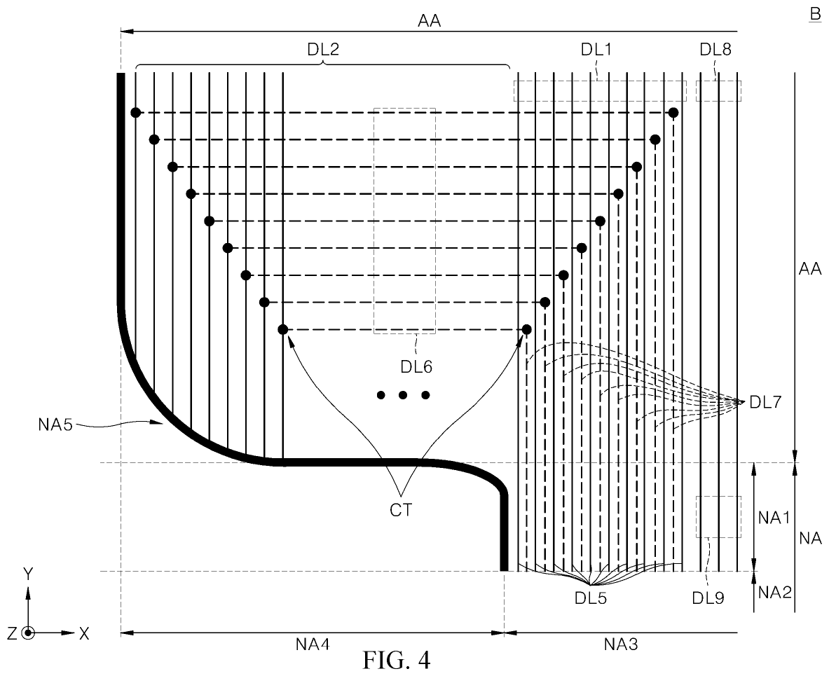

FIG. 4 is an enlarged view of an area B of FIG. 3 according to an embodiment of the present disclosure.

Referring to FIG. 4, the display panel 110 according to an embodiment of the present disclosure can include a first line DL1, a second line DL2, a fifth line DL5, a sixth line DL6, a seventh line DL7, an eighth line DL8, and a ninth line DL9. The display panel 110 can include the display area AA and the non-display area NA. The non-display area NA can include the first area NA1, the second area NA2, a third area NA3, a fourth area NA4, and a fifth area NA5.

In FIG. 4, each of the first line DL1, the second line DL2, and the eighth line DL8 can be the data line DL, and each of the fifth line DL5, the sixth line DL6, the seventh line DL7, and the ninth line DL9 can be the connection line or the link line. However, the present disclosure is not limited thereto. For example, each of all of the lines in FIG. 4 can be the data line DL. For example, each of all of the lines in FIG. 4 can be the power line PL.

A plurality of first lines DL1 can be disposed in the display area AA and can extend in the first direction (or the Y-axis direction). The first line DL1 can be a data line.

The plurality of first lines DL1 disposed in the display area AA can have the same length. Each of the plurality of first lines DL1 can be integrally connected to each of the plurality of fifth lines DL5 while each of the plurality of first lines DL1 and each of the plurality of fifth lines DL5 can be disposed in the same layer.

A plurality of second lines DL2 can be disposed in the display area AA and can extend in the first direction (or the Y-axis direction). The second line DL2 can be a data line.

The plurality of second lines DL2 disposed in the display area AA can have the same length. However, the present disclosure is not limited thereto. For example, lengths of some of the second lines DL2 contacting the fifth area (or a corner area) NA5 of the display panel 110 can be different from each other.

The plurality of fifth lines DL5 can be disposed in the first area NA1 and can extend in the first direction (or in the Y-axis direction). Each of the plurality of fifth lines DL5 can be a connection line which can be integrally connected, at one end thereof, to each of the plurality of first lines DL1. Each of the plurality of fifth lines DL5 can be the connection line which can be integrally connected, at the other end thereof, to each of the plurality of third lines DL3. The plurality of fifth lines DL5 disposed in the first area NA1 can have the same length. Each of the plurality of fifth lines DL5 can be integrally connected to each of the plurality of first lines DL1 while each of the plurality of fifth lines DL5 and each of the plurality of first lines DL1 can be disposed in the same layer. For example, the other end can be different from and be opposite to one end.

A plurality of sixth lines DL6 can be disposed in the display area AA and extend in the second direction (or the X-axis direction). Each of the plurality of sixth lines DL6 can be a connection line which can be connected, at one end thereof, to each of the plurality of second lines DL2. Each of the plurality of sixth lines DL6 can be the connection line which can be connected, at the other end thereof, to each of the plurality of seventh lines DL7.

Each of the plurality of sixth lines DL6 and each of the plurality of second lines DL2 can be disposed in different layers. For example, an insulating layer can be disposed between the sixth line DL6 and the second line DL2. However, the present disclosure is not limited thereto. For example, each of the plurality of sixth lines DL6 can directly contact (CT) and be electrically connected to each of the plurality of second lines DL2. For example, each of the plurality of sixth lines DL6 and each of the plurality of second lines DL2 can be electrically connected to each other via each of a plurality of contact holes formed in a layer disposed between each of the plurality of second lines DL2 and each of the plurality of sixth lines DL6. In various embodiments of the present disclosure, the contact (CT) between the plurality of sixth lines DL6 and the plurality of second lines DL2, respectively, can occur at various parts of the plurality of second lines DL2. For example, the contact (CT) between the plurality of sixth lines DL6 and the plurality of second lines DL2 can occur at intermediate parts of the plurality of second lines DL2, respectively, and need not occur at ends of the plurality second lines DL2, but such is not required. In various embodiments of the present disclosure, the contact between the plurality of sixth lines DL6 and the plurality of second lines DL2 can occur at ends of the plurality of second lines DL2, respectively, for example, ends of the plurality of second lines DL2 that are closest to the non-display area NA.

The plurality of sixth lines DL6 can have different lengths. The plurality of sixth lines DL6 can be arranged in an order toward the first area NA1 that lengths thereof in the second direction (or the X-axis direction) decrease in order to prevent intersection with the plurality of seventh lines DL7, respectively. For example, in a plan view, an overall shape of the arrangement of the sixth lines DL6 can be an inverted trapezoid.

Each of the plurality of sixth lines DL6 can intersect some of the second lines DL2 and/or some of the first lines DL1. For example, the sixth line DL6 which has the largest length can intersect at least a certain number of the second lines DL2, wherein the certain number can be obtained by subtracting 1 from the total number of the sixth lines DL6. For example, the sixth line DL6 having the largest length can intersect at least a certain number of the first lines DL1, wherein the certain number can be obtained by subtracting 1 or 2 from the total number of the sixth lines DL6.

A plurality of seventh lines DL7 can be disposed across the display area AA and the first area NA1 and can extend in the first direction (or the Y-axis direction). Each of the plurality of seventh lines DL7 can be a connection line which can be connected, at one end thereof, to each of the plurality of sixth lines DL6. Each of the plurality of seventh lines DL7 can be the connection line which can be connected, at the other end thereof, to each of the plurality of fourth lines DL4.

Each of the plurality of seventh lines DL7 and each of the plurality of sixth lines DL6 can be disposed in the same layer. For example, each of the plurality of seventh lines DL7 can directly contact and be electrically connected to each of the plurality of sixth lines DL6.

Alternatively, each of the plurality of seventh lines DL7 and each of the plurality of sixth lines DL6 can be disposed in different layers. For example, an insulating layer can be disposed between the seventh line DL7 and the sixth line DL6. However, the present disclosure is not limited thereto. For example, each of the plurality of seventh lines DL7 and each of the plurality of sixth lines DL6 can be electrically connected to each other via each of a plurality of contact holes formed in a layer disposed between each of the plurality of seventh lines DL7 and each of the plurality of sixth lines DL6.

The plurality of seventh lines DL7 can have different lengths. The plurality of seventh lines DL7 can be arranged in an order toward the fourth area NA4 that lengths thereof in the first direction (or the Y-axis direction) decrease in order to prevent intersection with the plurality of sixth lines DL6, respectively. For example, in a plan view, an overall shape of the arrangement of the seventh lines DL7 can be a shape of a combination of a rectangle and a right triangle. In various embodiments of the present disclosure, the contact (CT) between the plurality of sixth lines DL6 and the plurality of seventh lines DL7, respectively, can occur at various parts of the plurality of seventh lines DL7. For example, the contact (CT) between the plurality of sixth lines DL6 and the plurality of seventh lines DL7 can occur at intermediate parts of the plurality of seventh lines DL7, respectively, and need not occur at ends of the plurality seventh lines DL7, but such is not required. In various embodiments of the present disclosure, the contact between the plurality of sixth lines DL6 and the plurality of seventh lines DL7 can occur at ends of the plurality of seventh lines DL7, respectively, for example, ends of the plurality of seventh lines DL7 that are furthest from the non-display area NA.

Each of the plurality of seventh lines DL7 can be disposed in a different layer from a layer in which each of the plurality of first lines DL1 and each of the plurality of fifth lines DL5 are disposed. For example, an insulating layer can be disposed between a layer of each of the plurality of seventh lines DL7 and a layer of each of the plurality of first lines DL1 and each of the plurality of fifth lines DL5. However, the present disclosure is not limited thereto.

Each of the plurality of seventh lines DL7 can be disposed on top of each of the plurality of first lines DL1 and each of the plurality of fifth lines DL5. For example, in a plan view, each of the plurality of seventh lines DL7 can overlap a combination of each of the plurality of first lines DL1 and each of the plurality of fifth lines DL5. Alternatively, in a plan view, the plurality of seventh lines DL7 and combinations of the plurality of first lines DL1 and the plurality of fifth lines DL5 can be alternately arranged with each other.

A plurality of eighth lines DL8 can be disposed in the display area AA and can extend in the first direction (or the Y-axis direction). The eighth line DL8 can be the data line DL.

The plurality of eighth lines DL8 disposed in the display area AA can have the same length. Each of the plurality of eighth lines DL8 can be integrally connected, at one end thereof, to each of the plurality of ninth lines DL9 while each of the plurality of eighth lines DL8 and each of the plurality of ninth lines DL9 can be disposed in the same layer.

The plurality of ninth lines DL9 can be disposed in the first area NA1 and can extend in the first direction (or in the Y-axis direction). Each of the plurality of ninth lines DL9 can be a connection line which can be connected, at one end thereof, to each of the plurality of eighth lines DL8. Each of the plurality of ninth lines DL9 can be the connection line which can be connected, at the other end thereof, to each of a plurality of tenth lines.

The plurality of ninth lines DL9 disposed in the first area NA1 can have the same length. Each of the plurality of ninth lines DL9 can be integrally connected to each of the plurality of eighth lines DL8 while each of the plurality of eighth lines DL8 and each of the plurality of ninth lines DL9 can be disposed in the same layer.

The first area NA1 of the non-display area NA can be a partial area in which the connection lines such as the fifth line DL5, a portion of the seventh line DL7, and the ninth line DL9 are disposed. The first area NA1 can be disposed between the display area AA and the second area NA2.

The connection lines disposed in the first area NA1 need not intersect each other but can extend in a parallel manner to each other. The first area NA1 can be composed of two or more layers.

The second area NA2 of the non-display area NA can be the bent area where the connection line is disposed. The second area NA2 can be disposed between the first area NA1 and the display panel pad D-PD.

The second area NA2 can be bent toward the rear surface of the display panel 110 so as to have a predetermined curvature. Accordingly, the bezel area can be minimized by reducing the size of the non-display area NA constituting the front surface of the display device 100, the appearance characteristics of the display device 100 can be improved. For example, an area size of the front surface of the display device 100 corresponding to a half or greater of the length in the Y-axis direction of the second area NA2 can be reduced by bending the second area NA2.

The third area NA3 of the non-display area NA can be an area where the connection line from the display area AA is disposed. The third area NA3 can overlap a partial area of each of the first area NA1 and the second area NA2. A width of the third area NA3 can be based on a sum of widths of the display panel pads D-PD. For example, the width of the third area NA3 can correspond to the sum of the widths of the display panel pads D-PD.

The fourth area NA4 of the non-display area NA can be an area excluding the third area NA3 of the display panel 110. The fourth area NA4 can overlap a partial area of each of the first area NA1 and the second area NA2.

The fourth area NA4 is an area free of the connection line from the display area AA. The connection line from the non-display area NA can be disposed in the fourth area NA4. For example, the gate control line GCL or the like can be disposed in the fourth area NA4. However, the present disclosure is not limited thereto. For example, the gate line GL can be referred to as a first gate line, and embodiments of the present disclosure are not limited thereto. For example, the gate control line GCL can be referred to as a second gate line, and embodiments of the present disclosure are not limited thereto.

Lengths of the plurality of second lines DL2 disposed in the display area AA and the fourth area NA4 can be different from each other such that as the plurality of second lines DL2 are arranged in an order toward the third area NA3 such that the lengths of the plurality of second lines DL2 can increase. For example, a length of the second line DL2 disposed at one side of the fourth area NA4 can be smaller than a length of the second line DL2 disposed at the other side of the fourth area NA4 closer to the third area NA3. For example, the fifth area NA5 can be present in the display area AA due to the difference between the lengths of the plurality of second lines DL2.

The fourth area NA4 can further include the fifth area NA5 in addition to display area AA, the first area NA1, and the second area NA2. The fifth area NA5 can be a corner area. However, the present disclosure is not limited to the terms. The fifth area NA5 can belong to the non-display area NA, and the second line DL2 need not be disposed in the fifth area NA5.

Recently, there is an increasing demand for a variety of shapes (for example, a free form display device) of the display area AA of the display device 100 other than a rectangle shape. For example, in various wearable devices such as smart watches and smart phones, or personal smart devices, market demand for the display area AA having a shape of a circle or a quadrilateral with rounded corners is increasing. In the display device 100 according to the present disclosure, the display area AA need not have a rectangular shape.

When the shape of the display area AA is not rectangular, the lengths of the lines of the display area AA can be different from each other. For example, the lengths of the second lines DL2 occupying the display area AA are different from each other, there can be an area in which the second line DL2 is not disposed. For example, the fifth area NA5 can be included in the display panel 110 according to an embodiment of the present disclosure.

The first area NA1 can be included in a portion of the non-display area NA where the connection lines connected to the lines of the display area AA are disposed. Reducing the first area NA1 which is the non-display area NA can allow for implementing a narrow bezel or bezel-free display device. Accordingly, the inventors of the present disclosure have invented a display device having a structure in which the connection line to connect the second line DL2 to the display panel pad D-PD is bypassed along another path in order to reduce the height (or the length in the Y-axis direction) of the first area NA1. In embodiments of the present disclosure, the connection line in the non-display area NA, such as the first area NA1 need not extend diagonally, or become closer as shown in FIG. 3, but can extend in the first direction (e.g., the Y-axis direction) from the display area AA to the non-display area NA, in a parallel manner, for example, since the connection lines are disposed in the display area AA.

Each of the plurality of second lines DL2 of the display panel 110 can be connected to one end of each of the plurality of sixth lines DL6 at a predetermined point. For example, the second line DL2 and the sixth line DL6 can be disposed in different layers and can be connected to each other via a contact hole defined in a layer disposed therebetween. The other end of each of the plurality of sixth lines DL6 can be connected to one end of each of the plurality of seventh lines DL7. The other end of each of the plurality of seventh lines DL7 can be connected to each of the plurality of display panel pads D-PD. For example, the other end can be different from and opposite to one end.

The connection lines (for example, the sixth line DL6 and the seventh line DL7) connecting the second lines DL2 and the display panel pads D-PD to each other can be disposed in the display area AA. For example, all of the sixth lines DL6 can be disposed in the display area AA. For example, one end of the seventh line DL7 connected to the sixth line DL6 can be disposed in the display area AA, and the other end thereof can be disposed in the non-display area NA.

Since the non-display area NA where the connection line is not disposed can be reduced or removed, a narrow bezel can be implemented. The connection line disposed in the first area NA1 connects the display area AA and the second area NA2 to each other. Thus, the first area NA1 can be reduced or removed. For example, the fifth line DL5 and the ninth line DL9 can be removed. For example, the seventh line DL7 can only be disposed in the display area AA.

When the first area NA1 disposed between the display area AA and the second area NA2 is removed, the display area AA and the second area NA2 can come into contact with each other. For example, the display area AA and the second area NA2 can directly contact each other. For example, a portion of the display panel 110 in the second area NA2 can start to be bent at a position thereof in contact with the display area AA.

In the display device 100 according to the embodiment of the present disclosure, a path of the connection line between the second line DL2 and the display panel pad D-PD can be changed, and the area between the display area AA and the second area NA2 can be reduce or removed to reduce the non-display area NA, such that the narrow bezel can be implemented.

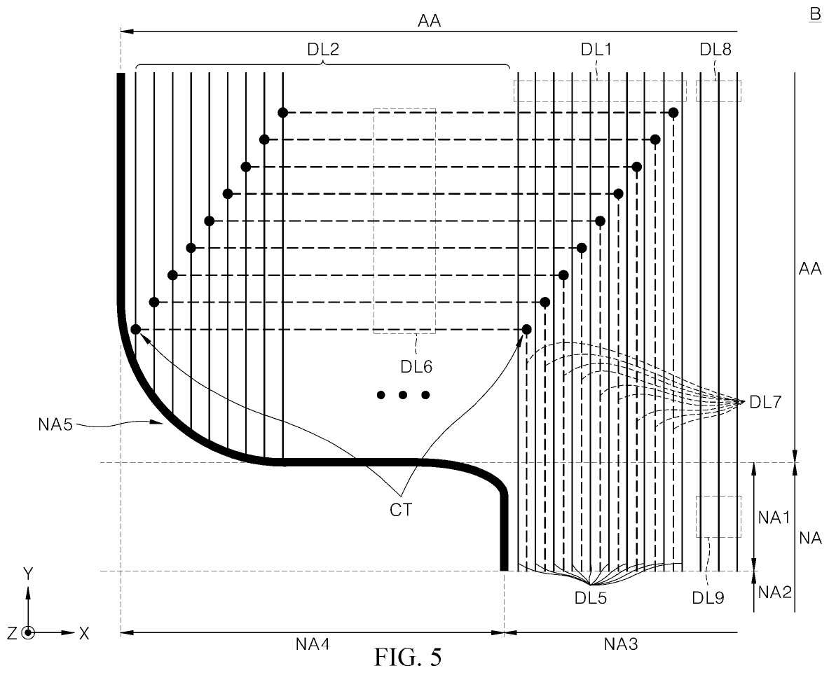

FIG. 5 is an enlarged view of an area B of FIG. 3 according to another embodiment of the present disclosure.

Referring to FIG. 5, the display panel 110 according to another embodiment of the present disclosure can include the first line DL1, the second line DL2, the fifth line DL5, the sixth line DL6, the seventh line DL7, the eighth line DL8, and the ninth line DL9. The display panel 110 can include the display area AA and the non-display area NA. The non-display area NA can include the first area NA1, the second area NA2, the third area NA3, the fourth area NA4, and the fifth area NA5. The description of the components in FIG. 5 are substantially the same as those in FIG. 4, and thus can be omitted or simplified.

A plurality of first lines DL1 can be disposed in the display area AA and can extend in the first direction (or the Y-axis direction). The first line DL1 can be a data line. The plurality of first lines DL1 disposed in the display area AA can have the same length.

A plurality of second lines DL2 can be disposed in the display area AA and can extend in the first direction (or the Y-axis direction). The second line DL2 can be a data line. Lengths of some of the second lines DL2 contacting the fifth area NA5 of the display panel 110 can be different from each other.

The plurality of fifth lines DL5 can be disposed in the first area NA1 and can extend in the first direction (or in the Y-axis direction). The fifth line DL5 can be a connection line. The lengths of the plurality of fifth lines DL5 can be equal to each other.

A plurality of sixth lines DL6 can be disposed in the display area AA and can extend in the second direction or the X-axis direction. One end of each of the plurality of sixth lines DL6 can be connected to each of the plurality of second lines DL2, and the other end thereof can be connected to each of the plurality of seventh lines DL7. Each of the plurality of sixth lines DL6 can be a connection line. For example, the other end can be different from and opposite to one end.

Each of the plurality of sixth lines DL6 and each of the plurality of second lines DL2 can be disposed in different layers. For example, each of the plurality of sixth lines DL6 and each of the plurality of second lines DL2 can be electrically connected to each other via each of a plurality of contact holes formed in a layer disposed between each of the plurality of second lines DL2 and each of the plurality of sixth lines DL6.

The plurality of sixth lines DL6 of the display device 100 according to another embodiment of the present disclosure can have the same length. The plurality of sixth lines DL6 can be arranged in an order toward the first area NA1 that spacings between the plurality of sixth lines DL6 and the eighth lines DL8 in the second direction (or the X-axis direction) increase in order to prevent intersection with the plurality of seventh lines DL7, respectively. For example, an overall arrangement shape of the sixth lines DL6 in a plan view can be a parallelogram.

Each of the plurality of sixth lines DL6 can intersect some of the second lines DL2 and/or some of the first lines DL1. For example, the sixth line DL6 contacting or connected to the outermost second line DL2 can intersect with at least the number of the second lines DL2 as many as the number obtained by subtracting 1 from the total number of the sixth lines DL6. For example, the sixth line DL6 contacting or connected to the innermost second line DL2 can intersect at least the number of the first lines DL1 as many as the number obtained by subtracting 1 or 2 from the total number of the sixth lines DL6. For example, the number of intersection points between one of the plurality of sixth lines DL6 and the first line DL1 and the second line DL2 can be equal to the number of intersection points between another of the plurality of sixth lines DL6 and the first line DL1 and the second line DL2.

A plurality of seventh lines DL7 can be disposed across the display area AA and the first area NA1 and can extend in the first direction or the Y-axis direction. One end of each of the plurality of seventh lines DL7 can be connected to each of the plurality of sixth lines DL6, and the other end thereof can be connected to each of the plurality of fourth lines DL4. Each of the plurality of seventh lines DL7 can be a connection line.

Each of the plurality of seventh lines DL7 and each of the plurality of sixth lines DL6 can be disposed in the same layer. However, the present disclosure is not limited thereto. For example, each of the plurality of seventh lines DL7 and each of the plurality of sixth lines DL6 can be disposed in different layers.

The plurality of seventh lines DL7 can have different lengths. The plurality of seventh lines DL7 can be arranged in an order toward the fourth area NA4 that lengths thereof in the first direction (or the Y-axis direction) decrease in order to prevent intersection with the plurality of sixth lines DL6, respectively. For example, in a plan view, an overall shape of the arrangement of the seventh lines DL7 can be a shape of a combination of a rectangle and a right triangle.

Each of the plurality of seventh lines DL7 can be disposed in a different layer from a layer in which each of the plurality of first lines DL1 and each of the plurality of fifth lines DL5 are disposed. For example, an insulating layer can be disposed between a layer of each of the plurality of seventh lines DL7 and a layer of each of the plurality of first lines DL1 and each of the plurality of fifth lines DL5. However, the present disclosure is not limited thereto.

Each of the plurality of seventh lines DL7 can be disposed on top of each of the plurality of first lines DL1 and each of the plurality of fifth lines DL5. For example, in a plan view, each of the plurality of seventh lines DL7 can overlap a combination of each of the plurality of first lines DL1 and each of the plurality of fifth lines DL5. Alternatively, in a plan view, the plurality of seventh lines DL7 and combinations of the plurality of first lines DL1 and the plurality of fifth lines DL5 can be alternately arranged with each other.

A plurality of eighth lines DL8 can be disposed in the display area AA and can extend in the first direction or the Y-axis direction. The eighth line DL8 can be the data line DL. The lengths of the plurality of eighth lines DL8 can be equal to each other.

A plurality of ninth lines DL9 can be disposed in the first area NA1 and can extend in the first direction or in the Y-axis direction. One end of each of the plurality of ninth lines DL9 can be connected to each of the plurality of eighth lines DL8, and the other end thereof can be connected to each of the plurality of tenth lines DL10. Each of the plurality of ninth lines DL9 can be a connection line. The lengths of the plurality of ninth lines DL9 can be equal to each other.

The first line DL1, the second line DL2, the fifth line DL5, the eighth line DL8, and the ninth line DL9 can be disposed in the same layer. The first line DL1 and the fifth line DL5 can be integrally formed with each other. The eighth line DL8 and the ninth line DL9 can be integrally formed with each other.

The first area NA1 can be an area where a connection line connecting the display area AA and the display panel pad D-PD to each other is disposed. The first area NA1 can be disposed between the display area AA and the second area NA2. A portion of the display panel 110 of the first area NA1 can be composed of two or more layers.

The second area NA2 can be a bent area where the connection line is disposed. The second area NA2 can be disposed between the first area NA1 and the display panel pad D-PD.

The second area NA2 can be bent toward the rear surface of the display panel 110. Thus, a size of a portion of the second area of the non-display area NA constituting the front surface of the display device 100 can be reduced such that the bezel area can be minimized and the appearance characteristics of the display device 100 can be improved.

The third area NA3 can be an area where the connection line from the display area AA is disposed. The third area NA3 can overlap a partial area of each of the first area NA1 and the second area NA2. A width of the third area NA3 can be based on a sum of widths of the display panel pads D-PD. For example, the width of the third area NA3 can correspond to the sum of the widths of the display panel pads D-PD.

The fourth area NA4 of the non-display area NA can be an area excluding the third area NA3 of the display panel 110. The fourth area NA4 can overlap a partial area of each of the first area NA1 and the second area NA2.

In order to respond to a market demand for a free form display device, the length of each of the plurality of second lines DL2 disposed in the display area AA and in the fourth area NA4 can gradually increase. For example, there can be the fifth area NA5 due to a difference between the lengths of the plurality of second lines DL2 in the display area AA.

The fourth area NA4 can further include the fifth area NA5 in addition to display area AA, the first area NA1, and the second area NA2. The fifth area NA5 can belong to the non-display area NA, and the second line DL2 need not be disposed in the fifth area NA5.

Since the non-display area NA where the connection line is not disposed can be reduced or removed, the narrow bezel can be implemented. Since the connection line disposed in the first area NA1 connects the display area AA and the second area NA2 to each other, the first area NA1 can be reduced or removed. For example, the fifth line DL5 and the ninth line DL9 can be removed. For example, the seventh line DL7 can be disposed in the display area AA only. But embodiments of the present disclosure are not limited thereto, and some portions of the seventh line DL7 can be located in the non-display area NA.

When the first area NA1 disposed between the display area AA and the second area NA2 is removed, the display area AA and the second area NA2 can come into contact with each other. For example, the display area AA and the second area NA2 can directly contact each other. For example, a portion of the display panel 110 in the second area NA2 can start to be bent at a position thereof in contact with the display area AA.

In the display device 100 according to the embodiment of the present disclosure, a path of the connection line between the second line DL2 and the display panel pad D-PD can be changed, and the area between the display area AA and the second area NA2 can be reduce or removed to reduce the non-display area NA, such that the narrow bezel can be implemented.

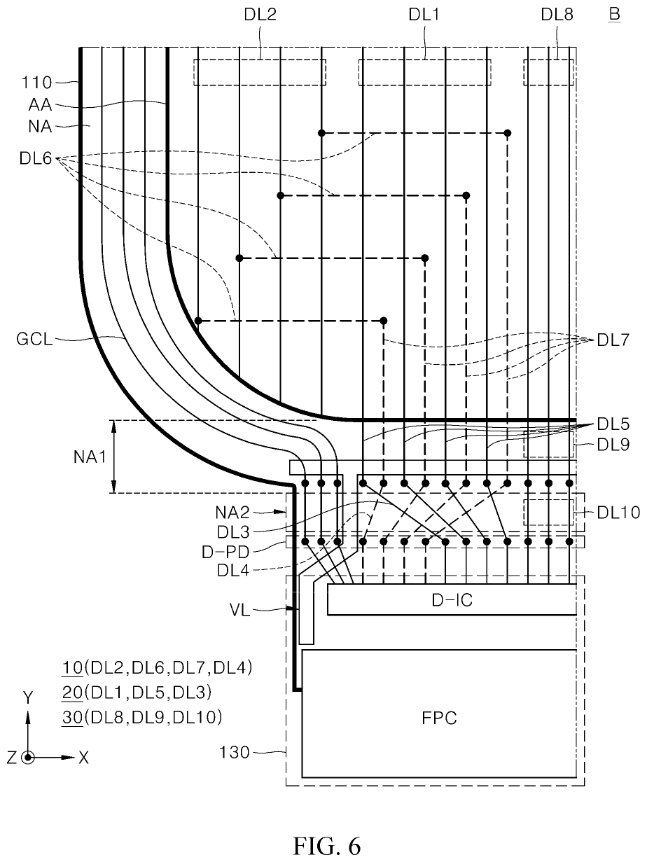

FIG. 6 is a view of an area B of FIG. 3 and an area around the area B according to an embodiment of the present disclosure.

Referring to FIG. 6, the display device 100 according to the embodiment of the present disclosure can include the first line DL1, the second line DL2, the third line DL3, the fourth line DL4, the fifth line DL5, the sixth line DL6, the seventh line DL7, the eighth line DL8, the ninth line DL9, and the tenth line DL10 disposed in the display panel 110. The display panel 110 can include the display area AA and the non-display area NA. The non-display area NA can include the first area NA1, the second area NA2, the third area NA3, the fourth area NA4, and the fifth area NA5. The description of the components in FIG. 6 are substantially the same as those in FIG. 5, and thus can be omitted or simplified.

A plurality of first lines DL1 can be disposed in the display area AA and can extend in the first direction (or the Y-axis direction). The first line DL1 can be a data line. The plurality of first lines DL1 disposed in the display area AA can have the same length.

A plurality of second lines DL2 can be disposed in the display area AA and can extend in the first direction (or the Y-axis direction). The second line DL2 can be a data line. Lengths of some of the second lines DL2 contacting the fifth area NA5 of the display panel 110 can be different from each other.

The plurality of fifth lines DL5 can be disposed in the first area NA1 and can extend in the first direction (or in the Y-axis direction). The fifth line DL5 can be a connection line. The lengths of the plurality of fifth lines DL5 can be equal to each other.

A plurality of sixth lines DL6 can be disposed in the display area AA and can extend in the second direction or the X-axis direction. One end of each of the plurality of sixth lines DL6 can be connected to each of the plurality of second lines DL2, and the other end thereof can be connected to each of the plurality of seventh lines DL7. Each of the plurality of sixth lines DL6 can be a connection line. For example, the other end can be different from and opposite to one end.

Each of the plurality of sixth lines DL6 and each of the plurality of second lines DL2 can be disposed in different layers. For example, each of the plurality of sixth lines DL6 and each of the plurality of second lines DL2 can be electrically connected to each other via each of a plurality of contact holes formed in a layer disposed between each of the plurality of second lines DL2 and each of the plurality of sixth lines DL6.

The plurality of sixth lines DL6 of the display device 100 according still another embodiment of the present disclosure can have the same length. The plurality of sixth lines DL6 can be arranged in an order toward the first area NA1 that spacings between the plurality of sixth lines DL6 and the eighth lines DL8 in the second direction (or the X-axis direction) increase in order to prevent intersection with the plurality of seventh lines DL7, respectively. For example, the sixth line DL6 connected to the outermost second line DL2 can be disposed at the lowest level in the first direction or the −Y axis direction. For example, an overall arrangement shape of the sixth lines DL6 in a plan view can be a parallelogram. Each of the plurality of sixth lines DL6 can intersect some of the second lines DL2 and/or some of the first lines DL1.

A plurality of seventh lines DL7 can be disposed across the display area AA and the first area NA1 and can extend in the first direction or the Y-axis direction. One end of each of the plurality of seventh lines DL7 can be connected to each of the plurality of sixth lines DL6, and the other end thereof can be connected to each of the plurality of fourth lines DL4. Each of the plurality of seventh lines DL7 can be a connection line.

Each of the plurality of seventh lines DL7 and each of the plurality of sixth lines DL6 can be disposed in the same layer. However, the present disclosure is not limited thereto. For example, each of the plurality of seventh lines DL7 and each of the plurality of sixth lines DL6 can be disposed in different layers.

The plurality of seventh lines DL7 can have different lengths. The plurality of seventh lines DL7 can be arranged in an order toward the fourth area NA4 that lengths thereof in the first direction (or the Y-axis direction) decrease in order to prevent intersection with the plurality of sixth lines DL6, respectively. For example, among the plurality of seventh lines DL7, the seventh line DL7 connected to the sixth line DL6 disposed at the lowermost level in the first direction or the Y-axis direction can have the smallest length. For example, in a plan view, an overall shape of the arrangement of the seventh lines DL7 can be a shape of a combination of a rectangle and a right triangle.

A plurality of eighth lines DL8 can be disposed in the display area AA and can extend in the first direction or the Y-axis direction. The eighth line DL8 can be the data line DL. The lengths of the plurality of eighth lines DL8 can be equal to each other.

A plurality of ninth lines DL9 can be disposed in the first area NA1 and can extend in the first direction or in the Y-axis direction. One end of each of the plurality of ninth lines DL9 can be connected to each of the plurality of eighth lines DL8, and the other end thereof can be connected to each of the plurality of tenth lines DL10. Each of the plurality of ninth lines DL9 can be a connection line. The lengths of the plurality of ninth lines DL9 can be equal to each other.

A plurality of third lines DL3 can be disposed in the second area NA2 and can extend in a third direction or in an oblique direction. One end of the third line DL3 can be connected to the fifth line DL5, and the other end thereof can be connected to the display panel pad D-PD. For example, the third line DL3 can act as a connection line. The third line DL3 can be integrally connected to the fifth line DL5. The third line DL3 and the fifth line DL5 can be disposed in the same layer. The plurality of third lines DL3 can have different lengths.

A plurality of fourth lines DL4 can be disposed in the second area NA2 and can extend in a reverse third direction or a reverse diagonal or oblique direction. One end of the fourth line DL4 can be connected to the seventh line DL7, and the other end thereof can be connected to the display panel pad D-PD. Each of the plurality of fourth lines DL4 can be a connection line. The fourth line DL4 can be integrally connected to the seventh line DL7. The fourth line DL4 and the seventh line DL7 can be disposed in the same layer. The plurality of fourth lines DL4 can have different lengths.

A plurality of tenth lines DL10 can be disposed in the second area NA2 and in the first direction or the Y-axis direction. One end of the tenth line DL10 can be connected to the ninth line DL9, and the other end thereof can be connected to the display panel pad D-PD. Each of the plurality of tenth lines DL10 can be a connection line. The tenth line DL10 can be integrally connected to the ninth line DL9 and can be disposed in the same layer as a layer in which the ninth line DL9 is disposed.

The first area NA1 can be an area where the connection line connecting the display area AA and the display panel pad D-PD to each other is disposed. The first area NA1 can be disposed between the display area AA and the second area NA2. A portion of the display panel 110 in the first area NA1 can be composed of two or more layers.

The second area NA2 can be a bent area where the connection line is disposed. The second area NA2 can be disposed between the first area NA1 and the display panel pad D-PD. The connection line extending across the second area NA2 can be connected to the line of the driving integrated circuit D-IC at the display panel pad D-PD.

For optimized placement and space (or area) utilization, lead lines of the driving integrated circuit D-IC can have the same arrangement order as an arrangement order in which the lines of the display area AA are arranged. For example, the arrangement order of the data lines DL of the display area AA can be the same as the arrangement order of the lead lines of the driving integrated circuit D-IC that apply a data driving voltage to the data lines DL, respectively. For example, the lead lines of the driving integrated circuit D-IC can have the same arrangement order as the arrangement order of the display panel pads D-PD.

In the second area NA2, the third line DL3, the fourth line DL4, and the tenth line DL10 can be disposed. The tenth line DL10 can be integrally formed with the eighth line DL8 and the ninth line DL9 and can extend in the first direction. The tenth line DL10, the eighth line DL8 and the ninth line DL9 can be disposed in the same layer. The third line DL3 and the tenth line DL10 can be disposed in the same layer.

In a plan view, an order in which the third line DL3 and the fourth line DL4 are arranged in one side of the second area NA2 can be different from an order in which the third line DL3 and the fourth line DL4 are arranged in the other side of the second area NA2.

For example, in a plan view, in one side of the second area NA2, the third lines DL3 and the fourth lines DL4 can be disposed to overlap each other or can be alternately arranged with each other.

For example, in a plan view, the arrangement order of the third line DL3 and the fourth line DL4 in the other side of the second area NA2 can be the same as the arrangement order of the first line DL1 and the second line DL2 in the display area AA. For example, in the other side of the second area NA2, the third lines DL3 can be consecutively arranged so as to be adjacent to each other. For example, in the other side of the second area NA2, the fourth lines DL4 can be consecutively arranged so as to be adjacent to each other.

The lengths of the third lines DL3 disposed in the second area NA2 can be different from each other. For example, the third lines DL3 disposed in one side of the second area NA2 can overlap with or can be alternately arranged with the fourth lines DL4 disposed in one side of the second area NA2. The third lines DL3 disposed in the other side thereof can be consecutively arranged. Thus, the length of the third lines DL3 can be different from each other.

The lengths of the fourth line DL4 disposed in the second area NA2 can be different from each other. For example, the fourth lines DL4 disposed in one side of the second area NA2 can overlap with or can be alternately arranged with the third lines DL3 disposed in one side thereof. The fourth lines DL4 disposed in the other side thereof can be consecutively arranged. Thus, the length of the fourth lines DL4 can be different from each other.

The third line DL3 and the fourth line DL4 in the second area NA2 can be disposed in different layers. For example, in the second area NA2, the third lines DL3 can extend in the third direction or the diagonal direction and can have different lengths from each other. The fourth lines DL4 can extend in the reverse third direction or the reverses oblique direction and can have different lengths. Thus, the third line DL3 and the fourth line DL4 can be disposed in different layers to minimize an electrical short circuit therebetween. For example, in a plan view, the third line DL3 and the fourth line DL4 can intersect each other.

The second area NA2 can be bent toward the rear surface of the display panel 110. Thus, a size of a portion of the second area of the non-display area NA constituting the front surface of the display device 100 can be reduced such that the bezel area can be minimized and the appearance characteristics of the display device 100 can be improved.

Referring to FIG. 6, the display device 100 according to the embodiment of the present disclosure can further include the gate control line GCL, the power voltage line VL, the driving integrated circuit D-IC, and the flexible circuit board FPC.

The gate control line GCL and the power voltage line VL can be disposed in the non-display area NA of the display panel 110.

The gate control line GCL can act as a connection line connecting the gate driver circuit 120 and the driving integrated circuit D-IC to each other. The gate control line GCL need not extend in a straight line along any one direction. For example, the gate control line GCL can extend in a curved manner. The gate control line GCL can extend across the first area NA1, the second area NA2, and the display panel pad D-PD so as to be connected to the driving integrated circuit D-IC.

The power voltage line VL can act as a connection line connecting the power line PL of the display area AA and a power source external to the display panel 110 to each other. One or more power voltage lines VL can be disposed. A plurality of power voltage lines VL can be disposed in different layers. For example, the power voltage line VL disposed in a first layer can be a line supplying VDD (driving power), and the power voltage line VL disposed in a second layer can be a line supplying VSS (base power).

The power voltage line VL can have various shapes. For example, each power voltage line VL can be individually and directly connected to the external power source. However, the present disclosure is not limited thereto. For example, the power voltage line VL can be configured to have a voltage division point (for example, a bar shape) positioned between the power line PL and the power source in order to prevent voltage drop. For example, the voltage division point of the power voltage line VL can be located in the first area NA1. However, the present disclosure is not limited thereto.

The flexible circuit board FPC can be bonded to the display panel 110 in a bonding process. The flexible circuit board FPC can be composed of a source printed circuit board and a film circuit board.

The driving integrated circuit D-IC can apply a driving signal voltage to various circuits and elements in the display panel 110. A position of the driving integrated circuit D-IC can vary. Referring to FIG. 6, the driving integrated circuit D-IC according to the embodiment of the present disclosure can be disposed in the non-display area NA of the display panel 110. However, the present disclosure is not limited thereto. For example, the driving integrated circuit D-IC can be disposed in a film circuit board of the flexible circuit board FPC or on a source printed circuit board according to a COF scheme.

The driving integrated circuit D-IC can be composed of a body in which an integrated circuit is packaged, and a lead line. As the integration level of the integrated circuit increases, a size of the driving integrated circuit D-IC can become smaller. However, there can be a predetermined spacing between adjacent lead lines for connection with an adjacent circuit line thereto. In a design of a device that connects (interfaces) the driving integrated circuit D-IC and the adjacent circuit to each other, the display device can be designed according to an arrangement order of the lead lines and a size of a lead line area.

In order to increase the bonding force in the second area (or the bent area) NA2 of the display panel 110 according to the embodiment of the present disclosure and reduce the restoring force in the second area, a width of the bent area can be minimized, and the lower limit of the width of the bent area can be a width of the driving integrated circuit D-IC.

The display panel 110 according to the embodiment of the present disclosure can be configured such that in order to maintain the minimum width of the bent area, positions of some of the connection lines can be changed such that all of the connection lines extend across the second area NA2.

In the display device 100 according to the embodiment of the present disclosure, the path of the connection line between the second line DL2 and the display panel pad D-PD can be changed, and the area between the display area AA and the second area NA2 can be reduced or removed to reduce the non-display area NA, such that the narrow bezel can be implemented.

Referring to FIG. 6, the display device 100 according to the embodiment of the present disclosure can include the display panel 110 composed of the display area AA and the non-display area NA including the first area NA1 and the second area NA2. The display panel 110 can include a first continuously-connected line 10, a second continuously-connected line 20, and a third continuously-connected line 30.

The first continuously-connected line 10 can include the second line DL2, the sixth line DL6, the seventh line DL7, and the fourth line DL4. The second continuously-connected line 20 can include the first line DL1, the fifth line DL5, and the third line DL3. The third continuously-connected line 30 can include the eighth line DL8, the ninth line DL9, and the tenth line DL10.

The first continuously-connected line 10 and the second continuously-connected line 20 can intersect each other in the display area AA. For example, in the display area AA, the sixth line DL6 of the second continuously-connected line 20 can intersect the first line DL1 of the first continuously-connected line 10.

The first continuously-connected line 10 and the second continuously-connected line 20 can intersect each other in the second area NA2. For example, in the second area NA2, the fourth line DL4 of the first continuously-connected line 10 and the third line DL3 of the second continuously-connected line 20 can intersect each other.

In the first area NA1, the first continuously-connected line 10 and the second continuously-connected line 20 can extend in a parallel manner to each other so as not to intersect each other. In a cross-sectional view, the seventh line DL7 of the first continuously-connected line 10 can be disposed on top of the fifth line DL5 of the second continuously-connected line 20 and can overlap or non-overlap (or in a staggered manner), in a vertical direction or the Z-axis direction, the fifth line DL5 of the second continuously-connected line 20. In the plan view, the fifth lines DL5 of the second continuously-connected line 20 and the seventh lines DL7 of the first continuously-connected line 10 can overlap each other or can be alternately arranged with each other.

The first continuously-connected line 10 and the second continuously-connected line 20 can be disposed in different layers. For example, an insulating layer can be disposed between the first continuously-connected line 10 and the second continuously-connected line 20.

The first line DL1, the fifth line DL5, and the third line DL3 of the second continuously-connected line 20 can be integrally formed with each other and can be disposed in the same layer. The sixth line DL6, the seventh line DL7, and the fourth line DL4 of the first continuously-connected line 10 can be integrally formed with each other and can be disposed in the same layer.

The second line DL2 of the first continuously-connected line 10 can be formed in the same layer as a layer in which the second continuously-connected line 20 is disposed. The second line DL2 disposed in one layer can be connected to the sixth line DL6 disposed in another layer via the contact hole.

The third continuously-connected line 30 can be disposed around the second continuously-connected line 20. For example, the eighth line DL8 and the ninth line DL9 of the third continuously-connected line 30 can be disposed adjacent to and extend in parallel to the first line DL1 and the fifth line DL5 of the second continuously-connected line 20. For example, the second continuously-connected line 20 and the third continuously-connected line 30 can be disposed in the same layer in the display area AA, the first area NA1, and the second area NA2.

Since all lines of the third continuously-connected line 30 extend in a straight line in the first direction, the third continuously-connected line 30 can include a center line of the display panel 110 in the first direction.

An order in which the first continuously-connected line 10, the second continuously-connected line 20, and the third continuously-connected line 30 are arranged in one end thereof can be the same as an order in which the first continuously-connected line 10, the second continuously-connected line 20, and the third continuously-connected line 30 are arranged in the other end thereof.

One end of each of the first continuously-connected line 10, the second continuously-connected line 20, and the third continuously-connected line 30 can be disposed in the display area AA. The first continuously-connected line 10, the second continuously-connected line 20, and the third continuously-connected line 30 can be arranged in one end thereof in this order in the second direction or the Y-axis direction.

The other end of each of the first continuously-connected line 10, the second continuously-connected line 20, and the third continuously-connected line 30 can be disposed in an area of the display panel pads D-PD. The first continuously-connected line 10, the second continuously-connected line 20, and the third continuously-connected line 30 can be arranged in the other end thereof in this order in the second direction or the Y-axis direction.

The first continuously-connected lines 10 can be arranged in a mirror symmetrical manner with each other around the third continuously-connected line 30. The second continuously-connected lines 20 can be arranged in a mirror symmetrical manner with each other around the third continuously-connected line 30. For example, the continuously-connected lines of the display panel 110 can be arranged in an order of a left first continuously-connected line 10, a right second continuously-connected line 20, the third continuously-connected line 30, a right second continuously-connected line 20, and a right first continuously-connected line 10 in the X-axis direction.

For example, the left and right first continuously-connected lines 10 can be arranged in a mirror symmetrical manner with each other around the third continuously-connected line 30. The left and right second continuously-connected lines 20 can be arranged in a mirror symmetrical manner with each other around the third continuously-connected line 30.

In the display panel 110 according to the embodiment of the present disclosure, all of the first continuously-connected line 10, the second continuously-connected line 20, and the third continuously-connected line 30 can be bent while extending across the second area NA2 in order to maintain the minimum width of the bent area.

In the display device 100 according to the embodiment of the present disclosure, the second continuously-connected line 20 and the first continuously-connected line 10 intersect each other in the display area AA in one direction, and then the second continuously-connected line 20 and the first continuously-connected line 10 intersect again each other in a reverse direction in the second area NA2. Thus, a length of the continuously-connected line disposed in the first area NA1 and the first area NA1 itself can be reduced or removed. For example, the paths of the continuously-connected lines can be changed, and the area between the display area AA and the second area NA2 can be reduced or removed to reduce the non-display area NA, such that the narrow bezel can be implemented.

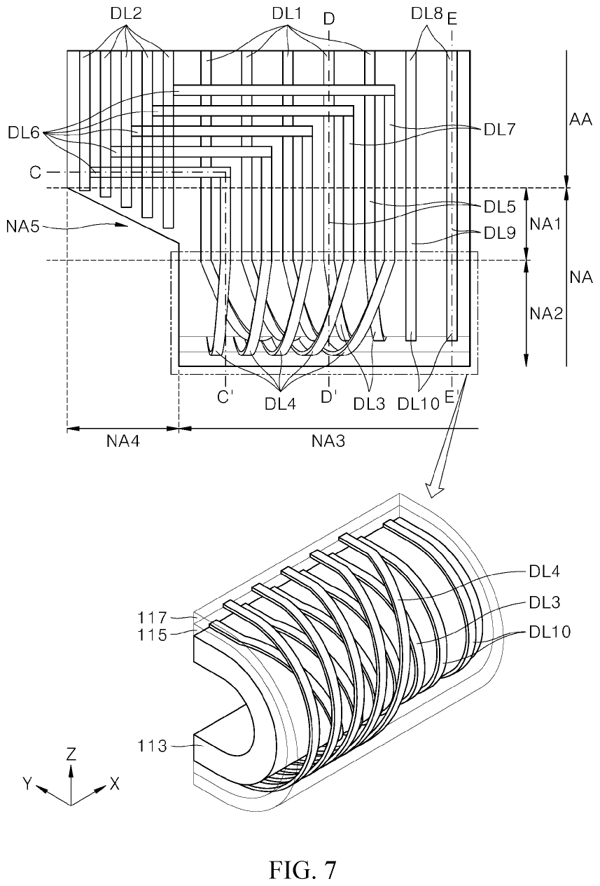

FIG. 7 is a three-dimensional diagram of the line DL according to an embodiment of the present disclosure.

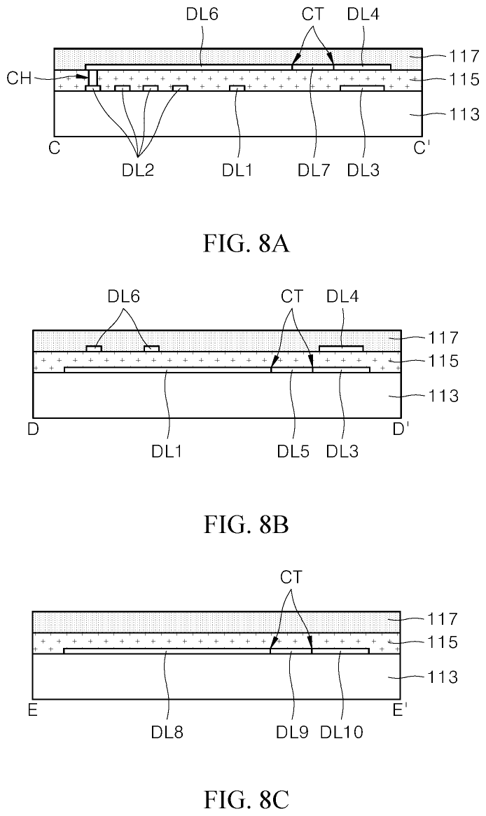

FIG. 8A to FIG. 8C are cross-sectional views of cutting lines C-C′, D-D′, and E-E′ in FIG. 7, respectively.

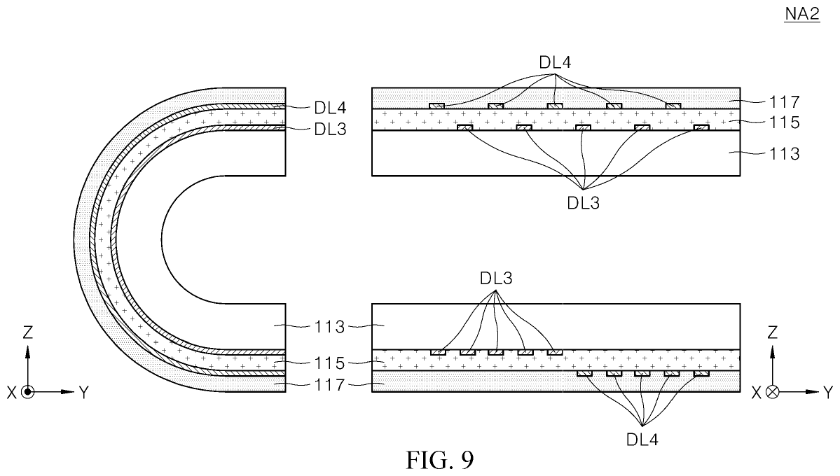

FIG. 9 is a cross-sectional view of the line DL disposed in the second area according to an embodiment of the present disclosure.

Referring to FIG. 7 to FIG. 9, the display device 100 according to the embodiment of the present disclosure includes the first line DL1, the third line DL3, the fourth line DL4, the fifth line DL5, the sixth line DL6, the seventh line DL7, the eighth line DL8, the ninth line DL9, and the tenth line DL10. The display panel 110 can include the display area AA and the non-display area NA. The non-display area NA can include the first area NA1, the second area NA2, the third area NA3, and the fourth area NA4. Descriptions of the components in FIG. 7 and FIGS. 8A to 8C are substantially the same as those in FIG. 6, and thus can be omitted or simplified.

A plurality of third lines DL3 can be disposed in the second area NA2 and extend in the third direction or in an oblique direction. One end of the third line DL3 can be connected to the fifth line DL5, and the other end thereof can be connected to the display panel pad D-PD. The third line DL3 can be the connection line. The third line DL3 can be integrally connected to the fifth line DL5, while the third line DL3 and the fifth line DL5 can be disposed in the same layer. The plurality of third lines DL3 can have different lengths.

A plurality of fourth lines DL4 can be disposed in the second area NA2 and can extend in a reverse third direction or a reverse diagonal or oblique direction. One end of the fourth line DL4 can be connected to the seventh line DL7, and the other end thereof can be connected to the display panel pad D-PD. Each of the plurality of fourth lines DL4 can be a connection line. The fourth line DL4 can be integrally connected to the seventh line DL7. The fourth line DL4 and the seventh line DL7 can be disposed in the same layer. The plurality of fourth lines DL4 can have different lengths.

Referring to FIG. 8A, the first line DL1 and the second line DL2 can be disposed on the substrate 113 and can extend in a parallel manner to each other. The second line DL2 dispose in or on a first layer 115 can be electrically contacted to the sixth line DL6 disposed in or on a second layer 117 via the contact hole CH. The sixth line DL6 disposed in the second layer 117 can extend in the second direction or X-axis direction, and can contact (CT) and be electrically connected to the seventh line DL7 which can be disposed in the first layer 115 and can extend in the first direction or Y-axis direction. The sixth line DL6 disposed in the second layer 117 can intersect the first line DL1 disposed in the first layer 115 and extending in the first direction or Y-axis direction. The seventh line DL7 disposed in the second layer 117 can contact (CT) and be electrically connected to the fourth line DL4 disposed in the second layer 117. The fourth line DL4 disposed in the second layer 117 can intersect the third line DL3 disposed in the first layer 115.

Referring to FIG. 8B, the first line DL1, the fifth line DL5, and the third line DL3 can be integrally connected to each other, and can be disposed in the same layer on the substrate 113. For example, the first line DL1 and the fifth line DL5 can contact (CT) and can be electrically connected to each other. For example, the fifth line DL5 and the third line DL3 can contact (CT) and can be electrically connected to each other. The sixth line DL6 can be disposed in the second layer 117 different from the first layer 115 in which the first line DL1 is disposed. The first line DL1 and the sixth line DL6 can intersect each other. The fourth line DL4 can be disposed in the second layer 117 different from the first layer 115 in which the third line DL3 is disposed. The third line DL3 and the fourth line DL4 can intersect each other.

A plurality of tenth lines DL10 can be disposed in the second area NA2 and can extend in the first direction or the Y-axis direction. One end of the tenth line DL10 can be connected to the ninth line DL9, and the other end thereof can be connected to the display panel pad D-PD. The tenth line DL10 can act as the connection line. The tenth line DL10 can be integrally connected to the ninth line DL9 while the tenth and ninth lines are disposed in the same layer.

Referring to FIG. 8C, the eighth line DL8, the ninth line DL9, and the tenth line DL10 can be integrally connected to each other and disposed in the same first layer 115 on the substrate 113. For example, the eighth line DL8 and the ninth line DL9 can contact (CT) and be electrically connected to each other. For example, the ninth line DL9 and the tenth line DL10 can contact (CT) and be electrically connected to each other.

The second area NA2 can be a bent area where the connection line is disposed. The second area NA2 can be disposed between the first area NA1 and the display panel pad D-PD. The connection line extending across the second area NA2 can be connected to the line of the driving integrated circuit D-IC at the display panel pad D-PD. A portion of the display panel 110 in the second area NA2 can be composed of two or more layers.

In the second area NA2, the third line DL3, the fourth line DL4, and the tenth line DL10 can be disposed. The tenth line DL10 can be integrally formed with the eighth line DL8 and the ninth line DL9 and can extend in the first direction, while the tenth line DL10. the eighth line DL8 and the ninth line DL9 can be disposed in the same first layer 115. The third line DL3 and the tenth line DL10 can be disposed in the same first layer 115.

In a plan view, an order in which the third line DL3 and the fourth line DL4 are arranged in one side of the second area NA2 can be different from an order in which the third line DL3 and the fourth line DL4 are arranged in the other side of the second area NA2.

For example, in a plan view, in one side of the second area NA2, the third lines DL3 and the fourth lines DL4 can be disposed to overlap each other or can be alternately arranged with each other.

For example, in a plan view, the arrangement order of the third line DL3 and the fourth line DL4 in the other side of the second area NA2 can be the same as the arrangement order of the first line DL1 and the second line DL2 in the display area AA. For example, in the other side of the second area NA2, the third lines DL3 can be consecutively arranged so as to be adjacent to each other. For example, in the other side of the second area NA2, the fourth lines DL4 can be consecutively arranged so as to be adjacent to each other.

The lengths of the third lines DL3 disposed in the second area NA2 can be different from each other. For example, the third lines DL3 disposed in one side of the second area NA2 can overlap with or can be alternately arranged with the fourth lines DL4 disposed in one side of the second area NA2. The third lines DL3 disposed in the other side thereof can be consecutively arranged. Thus, the length of the third lines DL3 can be different from each other.

The lengths of the fourth line DL4 disposed in the second area NA2 can be different from each other. For example, the fourth lines DL4 disposed in one side of the second area NA2 can overlap with or can be alternately arranged with the third lines DL3 disposed in one side thereof. The fourth lines DL4 disposed in the other side thereof can be consecutively arranged. Thus, the length of the fourth lines DL4 can be different from each other.

Referring to the cross section of the second area NA2 in FIG. 8, the third line DL3 can be formed in the first layer 115 on a top surface of the substrate 113 and can be embedded in the first layer 115. For example, the third line DL3 can be disposed between the substrate 113 and the first layer 115. The fourth line DL4 can be formed on a top surface of the first layer 115 and can be embedded in the second layer 117. For example, the fourth line DL4 can be disposed between the first layer 115 and the second layer 117. Each of the first layer 115 and the second layer 117 can be an insulating layer. However, the present disclosure is not limited thereto.

The third line DL3 and the fourth line DL4 in the second area NA2 can be disposed in different layers. For example, in the second area NA2, the third lines DL3 can extend in the third direction or the diagonal direction and can have different lengths from each other. The fourth lines DL4 can extend in the reverse third direction or the reverses oblique direction and can have different lengths. Thus, the third line DL3 and the fourth line DL4 can be disposed in different layers to minimize an electrical short circuit therebetween. For example, in a plan view, the third line DL3 and the fourth line DL4 can intersect each other.

According to an embodiment of the present disclosure, the first area NA1 can be reduced or removed by disposing the connection lines such as the sixth line DL6 and the seventh line DL7 in the display area AA. The order in which the lines intersecting with each other for the reduction or removal of the first area NA1 are arranged can be changed while the second area NA2 is bent toward the rear surface of the display panel 110. Thus, the size of the portion of the non-display area NA constituting the front surface of the display device 100 can be reduced such that the bezel area can be minimized and thus the appearance characteristics of the display device 100 can be improved.

A display device according to an embodiment of the present disclosure can be described as follows.

A first aspect of the present disclosure provides a display device comprising: a display panel including a display area and a non-display area, wherein the non-display area has a first area and a second area; a plurality of first lines and a plurality of second lines disposed in the display area and extending in a first direction; a plurality of third lines and a plurality of fourth lines disposed in the second area; a plurality of fifth lines connecting the plurality of first lines and the plurality of third lines to each other, respectively; and a plurality of sixth lines and a plurality of seventh lines connecting the plurality of second lines and the plurality of fourth lines to each other, respectively, wherein the plurality of sixth lines and the plurality of seventh lines are respectively connected to each other, wherein each of the plurality of sixth lines extends in a second direction different from the first direction, wherein each of the plurality of seventh lines extends in the first direction.

According to some implementations of the first aspect, each of the plurality of fifth lines extends in the first area.

According to some implementations of the first aspect, each of the plurality of fifth lines is connected to each of the plurality of first lines, while each of the plurality of fifth lines and each of the plurality of first lines are disposed in the same layer.

According to some implementations of the first aspect, each of the plurality of fifth lines is connected to each of the plurality of third lines, while each of the plurality of fifth lines and each of the plurality of third lines are disposed in the same layer.

According to some implementations of the first aspect, each of the plurality of sixth lines is disposed in the display area, wherein each of the plurality of sixth lines connects each of the plurality of second lines and each of the plurality of seventh lines to each other.

According to some implementations of the first aspect, each of the plurality of sixth lines and each of the plurality of second lines are disposed in different layers, and are connected to each other via each of contact holes.

According to some implementations of the first aspect, the plurality of sixth lines have the same length.

According to some implementations of the first aspect, the plurality of sixth lines have different lengths.

According to some implementations of the first aspect, one portion of each of the plurality of seventh lines is disposed in the display area and the other portion thereof is disposed in the non-display area.

According to some implementations of the first aspect, each of the plurality of seventh lines is connected to each of the plurality of sixth lines in the display area, wherein each of the plurality of seventh lines is connected to each of the plurality of fourth lines in the non-display area.

According to some implementations of the first aspect, each of the plurality of seventh lines and each of the plurality of sixth lines are disposed in different layers, and are connected to each other via each of contact holes.

According to some implementations of the first aspect, each of the plurality of seventh lines and each of the plurality of sixth lines are disposed in the same layer are connected to each other.

According to some implementations of the first aspect, each of the plurality of seventh lines and each of the plurality of fourth lines are disposed in the same layer and are connected to each other.

According to some implementations of the first aspect, the plurality of seventh lines have different lengths.

According to some implementations of the first aspect, each of the plurality of third lines and each of the plurality of fourth lines are disposed in different layers and in the second area, and intersect each other.

According to some implementations of the first aspect, an order in which the plurality of third lines and the plurality of fourth lines are arranged in one side of the second area is different from an order in which the plurality of third lines and the plurality of fourth lines are arranged in the other side of the second area.

According to some implementations of the first aspect, each of the plurality of third lines and each of the plurality of fourth lines are connected to a data driver circuit at the other side of the second area.

According to some implementations of the first aspect, each of the plurality of first lines and each of the plurality of second lines have the same length.

According to some implementations of the first aspect, lengths of the plurality of second lines are different from each other.

According to some implementations of the first aspect, the display device further comprises: an eighth line disposed in the display area; a ninth line disposed in the first area; and a tenth line disposed in the second area, wherein the eighth line, the ninth line, and the tenth line are connected to each other, and are disposed in the same layer, and extend in the first direction.

A second aspect of the present disclosure provides a display device comprising: a display panel including a display area and a non-display area, wherein the non-display area has a first area and a second area; and a first continuously-connected line and a second continuously-connected line disposed in the display panel, wherein the first continuously-connected line and the second continuously-connected line intersect each other in each of the display area and the second area.

According to some implementations of the second aspect, in the first area, the first continuously-connected lines and the second continuously-connected lines are alternately arranged with each other.

According to some implementations of the second aspect, an insulating layer is disposed between the first continuously-connected line and the second continuously-connected line.

According to some implementations of the second aspect, the display device further comprises a third continuously-connected line adjacent to the second continuously-connected line.

According to some implementations of the second aspect, the first continuously-connected lines are symmetrically arranged with each other around the third continuously-connected line, wherein the second continuously-connected lines are symmetrically arranged with each other around the third continuously-connected line.

According to some implementations of the second aspect, an order in which the first continuously-connected line, the second continuously-connected line, and the third continuously-connected line are arranged in one end thereof is identical with an order in which the first continuously-connected line, the second continuously-connected line, and the third continuously-connected line are arranged in the other end thereof,

According to some implementations of the second aspect, the second continuously-connected line and the third continuously-connected line are disposed in the same layer and in the display area, the first area, and the second area.

Although the embodiments of the present disclosure have been described in more detail with reference to the accompanying drawings, the present disclosure is not necessarily limited to these embodiments, and can be modified in a various manner in the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. A display device comprising:
a display panel including a display area and a non-display area, wherein the non-display area has a first area and a second area;
a plurality of first lines and a plurality of second lines both disposed in the display area and extending in a first direction;
a plurality of third lines and a plurality of fourth lines both disposed in the second area;
a plurality of fifth lines connecting the plurality of first lines and the plurality of third lines to each other, respectively; and
a plurality of sixth lines and a plurality of seventh lines connecting the plurality of second lines and the plurality of fourth lines to each other, respectively,
wherein the plurality of sixth lines and the plurality of seventh lines are respectively connected to each other,
wherein each of the plurality of sixth lines extends in a second direction different from the first direction, and
wherein each of the plurality of seventh lines extends in the first direction.

2. The display device of claim 1, wherein each of the plurality of fifth lines extends in the first area, or
wherein the plurality of fifth lines are respectively connected to the plurality of first lines, while each of the plurality of fifth lines and each of the plurality of first lines are disposed in the same layer.

3. The display device of claim 2, wherein the plurality of fifth lines are respectively connected to the plurality of third lines, while each of the plurality of fifth lines and each of the plurality of third lines are disposed in the same layer.

4. The display device of claim 1, wherein:
each of the plurality of sixth lines is disposed in the display area, and
the plurality of sixth lines respectively connect the plurality of second lines and the plurality of seventh lines to each other, or
wherein the plurality of sixth lines and the plurality of second lines are disposed in different layers, and are respectively connected to each other via respective contact holes.

5. The display device of claim 1, wherein the plurality of sixth lines have the same length, or different lengths.

6. The display device of claim 1, wherein one portion of each of the plurality of seventh lines is disposed in the display area and the other portion thereof is disposed in the non-display area.

7. The display device of claim 6, wherein:
the plurality of seventh lines are respectively connected to the plurality of sixth lines in the display area, and
the plurality of seventh lines are respectively connected to the plurality of fourth lines in the non-display area, or
wherein the plurality of seventh lines and the plurality of sixth lines are disposed in different layers, and are respectively connected to each other via respective contact holes, or
wherein the plurality of seventh lines and the plurality of sixth lines are disposed in the same layer and are respectively connected to each other, or
wherein the plurality of seventh lines and the plurality of fourth lines are disposed in the same layer and are respectively connected to each other.

8. The display device of claim 1, wherein the plurality of seventh lines have different lengths.

9. The display device of claim 1, wherein the plurality of third lines and the plurality of fourth lines are disposed in different layers and in the second area, and respectively intersect each other.

10. The display device of claim 9, wherein an order in which the plurality of third lines and the plurality of fourth lines are arranged in one side of the second area is different from an order in which the plurality of third lines and the plurality of fourth lines are arranged in the other side of the second area.

11. The display device of claim 10, wherein the plurality of third lines and the plurality of fourth lines are respectively connected to a data driver circuit at the other side of the second area.

12. The display device of claim 1, wherein each of the plurality of first lines and each of the plurality of second lines have the same length, or
wherein lengths of the plurality of second lines are different from each other.

13. The display device of claim 1, wherein the display device further comprises:
an eighth line disposed in the display area;
a ninth line disposed in the first area; and
a tenth line disposed in the second area,
wherein the eighth line, the ninth line, and the tenth line are connected to each other, and are disposed in the same layer, and extend in the first direction.

14. A display device comprising:
a display panel including a display area and a non-display area, wherein the non-display area has a first area and a second area; and
a first continuously-connected line and a second continuously-connected line disposed in the display panel,
wherein the first continuously-connected line and the second continuously-connected line intersect each other in each of the display area and the second area of the non-display area.

15. The display device of claim 14, wherein in the first area, the first continuously-connected lines and the second continuously-connected lines are alternately arranged with each other.

16. The display device of claim 15, wherein an insulating layer is disposed between the first continuously-connected line and the second continuously-connected line.

17. The display device of claim 14, wherein the display device further comprises a third continuously-connected line adjacent to the second continuously-connected line.

18. The display device of claim 17, wherein:
the first continuously-connected lines are symmetrically arranged with each other around the third continuously-connected line, and
the second continuously-connected lines are symmetrically arranged with each other around the third continuously-connected line, or
wherein an order in which the first continuously-connected line, the second continuously-connected line, and the third continuously-connected line are arranged in one end thereof is identical with an order in which the first continuously-connected line, the second continuously-connected line, and the third continuously-connected line are arranged in the other end thereof, or
wherein the second continuously-connected line and the third continuously-connected line are disposed in the same layer and in the display area, the first area, and the second area.

19. A display device comprising:
a display panel including a display area and a non-display area;
a plurality of first lines and a plurality of second lines both disposed in the display area and extending in a first direction;
a plurality of third lines and a plurality of fourth lines both disposed in the non-display area;
a plurality of fifth lines disposed in the non-display area and extending in the first direction, and connecting the plurality of first lines and the plurality of third lines to each other, respectively;
a plurality of seventh lines extending from the display area into the non-display area in the first direction; and
a plurality of sixth lines in the display area and extending in a second direction that intersects the first direction, the plurality of sixth lines and the plurality of seventh lines connecting the plurality of second lines and the plurality of fourth lines to each other, respectively.

20. The display device of claim 19, wherein the plurality of third lines extend in a third direction and the plurality of fourth lines extend in a fourth direction, the third and fourth directions being different from the first and second directions, and
wherein the third direction and the fourth direction intersect.
